(19) United States
(12) Patent Application Publication
(10) Pub. No.: US 2022/0241897 A1
(43) Pub. Date: Aug. 4, 2022

(54) GLASS COMPOUND ARRANGEMENT

(71) Applicant: SCHOTT Primoceler Oy, Tampere (FI)

(72) Inventors: Jens Ulrich Thomas, Stralsund (DE); Antti Määttänen, Tampere (SE)

(73) Assignee: SCHOTT Primoceler Oy, Tampere (FI)

(21) Appl. No.: 17/726,937

(22) Filed: Apr. 22, 2022

Related U.S. Application Data
(63) Continuation of application No. PCT/EP2020/079486, filed on Oct. 20, 2020.

(30) Foreign Application Priority Data
Oct. 24, 2019 (EP) 19205115.9

(51) Int. Cl. B23K 26/20; H01L 23/08; H01L 23/10; H01L 23/48; B23K 26/06; B23K 26/0622; B23K 26/324; C03B 23/24

(52) U.S. Cl. CPC B23K 26/206; H01L 23/08; H01L 23/10; H01L 23/481; B23K 2103/54; B23K 26/0622; B23K 26/324; C03B 23/245; B23K 26/0608

(57) ABSTRACT

A substrate stack includes: at least two substrates including a base substrate and a cover substrate; at least one first laser weld line for welding the base substrate and the cover substrate; and at least one second beam spot or at least one second laser weld line at least one of situated next to the at least one first laser weld line or positioned such that a stress reduction in the at least one first laser weld line is achieved by the at least one second beam spot or second laser weld line, thus improving the mechanical stability of the substrate stack.

### CROSS REFERENCE TO RELATED APPLICATIONS

This is a continuation of International Patent Application No. PCT/EP2020/079486 entitled “GLASS COMPOUND ARRANGEMENT,” filed on Oct. 20, 2020, which is incorporated in its entirety herein by reference. International Patent Application No. PCT/EP2020/079486 claims priority to European Patent Application No. EP 19205115.9 filed on Oct. 24, 2019, which is incorporated in its entirety herein by reference.

### BACKGROUND OF THE INVENTION

### 1. Field of the Invention

The invention is related to a glass compound arrangement, for example for providing a hermetically sealed compartment in at least two layers of said glass compound arrangement, as well as a manufacturing process for making the same.

### 2. Description of the Related Art

Glass and glass like enclosures can be used, for example, to protect electronics, circuitry or sensors. It is possible to use hermetically sealed implementations of aforementioned enclosures for medical implants, for example, in a therapy to cure a heart disease, or for example in a retina or for any type of bio-processor. Known are bio-processors which are made from titanium.

What is needed in the art is a way to protect sensitive devices, such as sensors, in harsh climate conditions.

### SUMMARY OF THE INVENTION

In some exemplary embodiments provided according to the present invention, a substrate stack includes: at least two substrates, the at least two substrates including a base substrate and a cover substrate; at least one first laser weld line for welding the base substrate and the cover substrate; and at least one second beam spot or at least one second laser weld line at least one of situated next to the at least one first laser weld line or positioned such that a stress reduction in the at least one first laser weld line is achieved by the at least one second beam spot or second laser weld line, thus improving the mechanical stability of the substrate stack.

In some exemplary embodiments provided according to the present invention, an enclosure includes: a substrate stack including: at least two substrates, the at least two substrates including a base substrate and a cover substrate, the base substrate and the cover substrate constituting at least a part of the enclosure; at least one first laser weld line for welding the base substrate and the cover substrate, the at least one first laser weld line having a height in a direction perpendicular to its connecting plane; and at least one second beam spot or at least one second laser weld line at least one of situated next to the at least one first laser weld line or positioned such that a stress reduction in the at least one first laser weld line is achieved by the at least one second beam spot or second laser weld line, thus improving the mechanical stability of the substrate stack; and a function zone situated such that it is at least partly enclosed in the enclosure.

In some exemplary embodiments provided according to the present invention, a method of providing an enclosure enclosing a function zone is provided. The method includes: providing a base substrate and aligning a cover substrate above the base substrate in such a way that at least one contact surface is arranged between the base substrate and the cover substrate; hermetically sealing the function zone by introducing a first laser weld line in the enclosure; introducing a second laser weld line at the same position as the first laser weld line or at a position close to or overlapping with the first laser weld line; and relieving stress in an area of the first laser weld line of the enclosure by introducing the second laser weld line.

### BRIEF DESCRIPTION OF THE DRAWINGS

The above-mentioned and other features and advantages of this invention, and the manner of attaining them, will become more apparent and the invention will be better understood by reference to the following description of embodiments of the invention taken in conjunction with the accompanying drawings, wherein:

FIG. 1A a schematic cross-sectional side view of an enclosure;

FIG. 1B is a detail of FIG. 1 showing laser weld lines;

FIG. 1C is a cross-sectional side view of another embodiment comprising five substrate layers;

FIG. 2 is a schematic top view of an enclosure;

FIG. 3 is a cross-sectional side view along a laser weld line in an enclosure;

FIG. 4 is a cross-sectional view of a laser spot zone;

FIG. 5 is an example of tempering a previous weld line;

FIGS. 6 to 15 illustrate an exemplary method of making an enclosure/several enclosures;

FIG. 16 is a cross-sectional side view of an enclosure when tempering the edges of a cavity;

FIG. 17 is a cross-sectional side view of a multi-layered enclosure, where several cavities are arranged in each enclosure;

FIG. 18 is a side view detail of a multi-layered enclosure;

FIG. 19 is a cross-sectional side view of a multi-layered enclosure, for example as a hermetical biomedical implant;

FIG. 20 is a top view of a multi-layered enclosure;

FIG. 21 is a bottom view of a multi-layered enclosure;

FIG. 22 is a cross-sectional side view of another example of a multi-layered enclosure;

FIG. 23 is a bottom view of the multi-layered enclosure;

FIG. 24 is a cross-sectional side view of yet another example of a multi-layered enclosure for a plug-type connector;

FIG. 25 is a cross-sectional side view of yet another example of a multi-layered enclosure with an interface;

FIG. 26 is a cross-sectional side view of yet another example of a multi-layered enclosure with multiple electrical contacts; and

FIG. 27 is a photograph of multiple weld lines in and around the contact surface of two substrates.

Corresponding reference characters indicate corresponding parts throughout the several views. The exemplifications set out herein illustrate embodiments of the invention and such exemplifications are not to be construed as limiting the scope of the invention in any manner.

### DETAILED DESCRIPTION OF THE INVENTION

Sensors can be protected by exemplary embodiments provided according to the invention e.g. for the use in particular rough climate conditions. Further examples are Micro-Electro-Mechanic-Systems (MEMS), a pressure sensor, blood gas sensor, a glucose meter such as a blood glucose meter or the like.

Further fields of usage for the present invention can be found in protection sleeves for cell phones, wearables, in the field of virtual reality and augmented reality goggles and headsets and similar devices. For example, exemplary embodiments provided according to the invention may also be used in the scope of electromobility, in aviation and space environment, in high temperature environments and in the field of micro optics.

The previously mentioned applications all concern some form of electronic device, which is faced with rough environmental conditions and which thus has to be especially robust—or protected from these conditions. So, for example, in order to allow for the use of any electronics, which may be expected not to survive the before-mentioned environmental conditions, but which may be made cheaper or where even no rough electronics exist which could withstand in this conditions, exemplary embodiments provided according to the invention may be used to protect such devices like electronics.

Further, the invention allows to some extent an exchange or way of communication with the inner region of the device provided according to the invention, e.g. the enclosure, or the cavity situated inside the enclosure. This exchange or way of communication can be realized e.g. by electromagnetic radiation e.g. in visible light region and/or in the region of microwave radiation. For realization of the same, the enclosure is, at least in part and/or at least for a range of wave lengths, transparent. This transparency allows for communication methods, for any kind of data or energy transmission, and for measurements with and by electronics or sensors situated inside a cavity. In particular, optical communication methods or optical data or energy transmission is possible.

However, implementing a cavity in the enclosure is only an embodiment for possible usages of the invention. As will be understood below, the invention is not limited to cavities, but it can be used for improving also enclosures having cavities. In fact, the present invention can already be implemented just in a substrate stack.

It is principally known to put several parts or layers and to arrange them such that in an inner region components can be situated. For example European Patent EP 3 012 059 B 1 shows a method for manufacturing a transparent component for protecting an optical component. A new laser welding method is used therein.

The present invention may be seen in the vicinity of improving reliability and/or robustness of substrate stacks and/or enclosures, e.g. regarding environmental conditions.

Exemplary embodiments provided according to the invention can increase the mechanical stability of the substrate stack and/or enclosure.

According to the invention, a hermetically sealed enclosure comprises at least a base substrate and a cover substrate, which constitute at least a part of the enclosure. A function zone is situated such that it is circumferentially enclosed in the enclosure, e.g. surrounded by said base substrate and said cover substrate. Said substrates can be of a variety of materials e.g. ranging from homogenous ones like glass or monocrystalline silicon wafers to more complex substrates like a chemical hardened glass that is covered with a multilayer optical coating.

At least the cover substrate of the enclosure comprises, for example, a glass or glass-like material, e.g. glass ceramics or crystallines. Furthermore, silicone-based substrates as base and/or cover substrate can be used, also in combination with the glass or glass-based substrates. The base substrate and the cover substrate are hermetically welded by at least one laser weld line. The laser weld line is typically obtained by shooting a short-pulsed laser beam from a laser source into the material with a defined wavelength and energy so that a series of beam spots is placed into the material of the enclosure at each laser focus which is set in the laser source.

For doing so, the laser source may, for example, be set up such, that the cumulated thermal energy placed in several close-by beam spots sums up to an amount which is sufficient to melt the material in the melting zone. This can be achieved, for example, as several beam spots overlap each other, so that continuously thermal energy is deposited along the laser weld line and the limited area of the melting zone is heated sufficiently so that melting of the material in the melting zone is achieved.

At the same time, heat dissipation from the laser weld line into the substrate stack (enclosure) during the welding process may be critical. For example, when some electric or electronic device or component is arranged in the function zone (cavity) of the enclosure, the same might have to be protected from overheating and/or from any heat transfer into the device or component exceeding certain thresholds. For this, it may be advantageous that thermal energy introduced at one time, which is during application of one laser weld line, is limited and the substrate stack (enclosure) is not kept as a whole at higher temperature levels.

According to the process presented herein, in a first course of action the first laser weld line is applied, where only a limited amount of energy just sufficient to locally melt the material in the melting zone of each laser spot is introduced into the material. This thermal energy dissipates into the rest of the substrate stack (enclosure), but is so low, that even close by the laser weld line the temperature rise is sufficiently low. After applying the first laser weld line, the substrate stack (enclosure) may even be given enough time to cool down and/or for that heat could dissipate throughout the substrate stack (enclosure) so that no or only small amount of heat accumulation persists in the laser weld line.

Thereafter, and maybe after a cooling period in between the application steps of the two laser weld lines, the second laser weld line is applied. Again, the thermal energy introduced by the second (or any consecutive laser weld line) is spatially limited to the weld line itself, where the heat dissipates into the substrate stack (enclosure) but without forcing prominent temperature rise in the rest of the material, and/or in any object/device placed in the function zone (cavity). Therefore, placing two laser weld lines close to each other, or even overlapping each other, does not accumulate heat in the substrate stack (enclosure), or at least not in a critical amount, thus protecting the devices/components from overheating.

For example, if the substrate stack (enclosure), or even only the region of the laser weld line was preheated before application of the laser weld line, and/or if it was necessary to introduce prominent further heat into the substrate stack (enclosure) after application of the laser weld line has been performed in order to slow down the cooling of the laser weld line, then some critical amount of thermal energy might be introduced into the substrate stack (enclosure) and any device/component installed in the function zone (cavity) could be harmed. Therefore, the process as presented in this specification is advantageously also when it comes to installation of any device/component in the vicinity of any laser weld line, but also in this case allows for significant reduction or relief of stress in the substrate stack (enclosure).

As has been outlined before, by placing in the same process step the beam spots so close together that the resulting nonlinear absorption zone at least is in contact with the neighboring nonlinear absorption zone of the same laser weld line, or even overlaps with it, a restricted heat accumulation can occur in the region to be welded, and a continuous welding “line” is obtained. In some aspects, this can be seen quite similar to known welding methods e.g. for welding metal, where it is also possible even by a point-by-point spot-welding method to obtain a near-to-continuous weld line in the metal in the end. Therein, for example, energy deposition may be adjusted such that with one beam spot no melting of material is initiated, so that less energy is deposited than what is necessary for melting. But by placing several beam spots sufficiently close to each other, in sum enough thermal energy is deposited to just melt the material in the melting zone. Either of these exemplary embodiments can be implemented in the method alone or in combination in order to improve protection of any device/component in the function zone (cavity).

In other words, in order to form an enclosure in a first step a first substrate (base substrate) and at least a second substrate (cover substrate) are provided, where the at least one second substrate (cover substrate) comprises, for example, transparent material, which is, that the second substrate (cover substrate) is transparent at least in part or at least in a region of the second substrate and at least for a group of wave lengths. The at least one second substrate (cover substrate) is provided, for example, directly overneath the first substrate (base substrate), so that, for example, the second substrate (cover substrate) covers the function zone (cavity), where the first substrate may provide for an underside of the function zone (cavity).

First and second substrate together establish a contact area or contact zone, which is situated where the first substrate comes in contact with the second substrate. Each enclosure thus comprises at least one contact area. Thereafter, the function zone (cavity) is hermetically sealed by introducing said laser weld line along the contact area, for example, along a line around the rim of the enclosure. For example, several enclosures can be produced in a shared substrate stack which is big enough to provide for several enclosures, for example a wafer stack. In this case, each enclosure can then be separated afterwards by a separation step.

The laser weld line comprises a height HL in a direction perpendicular to its connecting plane. The connecting plane is the direction, in which the neighboring or consecutive beam spots are set. Typically, the laser welding is performed from an “above” perspective, in such a meaning, that the substrate stack is positioned e.g. on a surface—such as a table—and that the laser is shot from above at least through the uppermost substrate layer—or through more than one substrate layers—to the place of the beam focus. The height HL thus is measured in the direction of the laser beam, where the width of the laser weld line is measured perpendicular with respect to the direction of the laser beam.

When defining a first laser weld line in a certain amount of material in the enclosure, it may occur that a thermal stress is induced locally in that certain amount of material, for example in a region around the laser weld line. It thus may be the case, that the certain amount of material comprises a lower mechanical stability when one laser weld line has been defined. As this, it has been found out, that also the enclosure as a whole may comprise a lower mechanical stability when only one laser weld line is provided for each contact surface.

Surprisingly, it has been found that when a second laser weld line is placed close to the first laser weld line, the same amount of material in the enclosure may achieve an improved mechanical stability, even improved with respect to the situation without any laser weld line. So to say, by defining the second laser weld line in the enclosure, which at least overlaps with the first laser weld line, it is possible to reduce thermal stress at least in said amount of material. Additionally, it is possible to reduce also thermal stress in the enclosure as a whole when positioning the second laser weld line overlapping with the first laser weld line.

The enclosure as described herein comprises an improved mechanical stability. This said, the mechanical stability may be improved by introducing at least two laser weld lines for each contact surface, wherein in between each two neighboring substrate layers there is situated one contact surface. Additionally, the mechanical stability can be further improved when at each side of each contact surface there is at least one laser weld line overlapping with the laser weld line positioned at the other side of the same contact surface.

Additionally, or in other words, the mechanical stress in the at least one laser weld line is reduced, thus improving the mechanical stability of the hermetically sealed enclosure as a whole. This means, that by introducing an additional laser weld line into the material, and which overlaps with an “older” laser weld line which has already been placed in the material before, mechanical stress can be reduced or even eliminated in the material.

So to say, the mechanical stress in the at least one laser weld line, being the “older” laser weld line which is already placed in the material, is reduced by a stress reduction process step, and/or by a crack reduction step. During the stress reduction process step (which may also involve said crack reduction) any stress in the stress zone nearby the new laser spot can be changed. Depending on, among other adjustable features, where the new laser spot is set in the material, this may involve an increase of stress or a decrease up to ceasing of stress in the material.

The new laser spots can advantageously be set as another weld line, but it is not necessarily limited to this. So in other words, by thoughtful placement of laser spots, without the need of lining up the second laser spots in a sequence of a weld line, the stress can also be reduced. But the enclosure may comprise at least a second laser weld line situated next to the first laser weld line and/or situated such that a stress reduction is achieved by the second laser weld line. This is an exemplary embodiment, as in the case when the second laser spots are set in the same sequence as the first ones, meaning that a second laser weld line is placed next to the first laser weld line, it can be assured in an easy manner that the stress introduced by the first laser weld line is eliminated throughout the material. However, also placing several laser spots distributed around or along the first laser weld line without establishing a continuous, e.g. non-interrupted, sequence of spots is understood as said second laser weld line.

The first laser weld line may introduce a stress zone in the enclosure, where in the stress zone in inner stress or tension persists in the solidified material.

The second laser weld line may therefore advantageously be positioned in or next to the stress zone induced by the first laser weld line. By this, the second laser weld line interacts with said stress zone, and can even eliminate the stress zone positioned next to the second laser weld line. In other words, the second laser weld line relieves the stress zone so that a stress-free or nearly stress-free zone is established, and/or so that the laser welded enclosure is stress-free or nearly stress-free.

The enclosure may comprise a cavity inside the enclosure, which may be, that said function zone is said cavity enclosed inside the enclosure. Residual stress in the area of the cavities of a package can be especially critical because damage of the package is most often observed in the region where cavity reaches the frame of the package. It may be advantageous to place an at least two-dimensional laser weld line around the cavity for tempering the edges of the cavity, which is, for tempering the material situated around the cavity. By this, the inner side of the enclosure, which is surrounding the cavity or the cavities in the enclosure, can be tempered and strengthened, so that it may be more resistive with respect to any forces from inside or outside. For example, the inside of the cavity may comprise a higher or lower pressure as compared to the outside of the enclosure, thus introducing additional tension forces by the pressure difference. When the material surrounding the cavity/cavities in the enclosure is tempered, the enclosure can withstand higher forces without breaking or functional losses.

The at least one laser bond line can be designed to circumfere the function zone in a distance DF. This distance can be set as equal around the function zone. As an example, the distance may correspond to the height HL or less, or corresponds to double the height HL or less.

Each laser bond line may be situated such that it extends into two different substrates of the enclosure, wherein for example the laser bond line extends from the base cover layer into its neighboring layer, e.g. the top cover layer, and wherein the laser bond line welds the two different substrates with each other.

The enclosure may comprise an elastic or flexible layer, in particular as an intermediate layer between other layers, so that the hermetically sealed enclosure is deformable e.g. by pressure change or by a mechanical force. By such an elastic layer, the enclosure could be used e.g. as an adjustable lens.

The enclosure can further be embodied to comprise an inner coating zone, positioned for example around the function zone. For example, the welding process using the laser source can be directed to change a material property on the surface areas directly surrounding the function zone/the cavity. This corresponds to putting a coating on said surface areas.

Further, each substrate may comprise multiple layers and be provided as a multilayer compound. So in other words, multilayer compounds can be used and adjoined by the laser welding process. This may include, that a multilayer compound is prepared in advance and is welded as a whole in the manufacturing process with one or more other substrates to provide for said enclosure.

By comprising multilayer compounds, further material properties can be added to the enclosure in an easy way. For example, such a multilayer compound can comprise a pre-stress, or a defined pre-stress direction, so that when laser bonding such a multilayer compound the inner stress level of the multilayer compound can enhance for example the resistance of the enclosure, e.g. be a hardened multilayer compound. Thus an even improved hardening may result for the enclosure as a whole. Additionally or alternatively, such a multilayer compound can comprise a coating layer, for example a coating layer which is difficult to weld by laser welding, so that some of or all of the intermediate compound layers are provided as a “pack” or “stack” already sticked together. Such a coating may comprise an optical coating.

Glass or glass-like substrates, where an optical coating has been added on the front or back side or both, can also be welded to other substrates (coated or not) and subsequently hardened. In some embodiments, the substrate which comprises coating is at least partly transparent at the emitting wavelength of the welding laser, if it extends into the planned beamline of the welding laser. For example, a substrate with a reflective coating in the VIS wavelength regime is achieved by sputtering several alternating thin layers of Titanium Oxide and Silicon Oxide. Here welding can be achieved with a laser emitting in the NIR.

The enclosure may comprise any number of additional intermediate layers positioned in between the base layer and the cover layer, for example three intermediate layers.

The function zone may be situated in the or one of the intermediate layer(s). In this configuration, the function zone can be covered by said base layer on its bottom side and/or by said cover layer on its top side.

The function zone can be designed as a cavity, wherein a function component such as an electrical component can be arranged in said cavity to be protected by the enclosure.

The hermetically sealed enclosure can comprise one or more function component(s) comprising a power semiconductor, such as a GaN-LED, a SiC-, GaAs- or GaN- power transistor being positioned inside the cavity. Additionally or alternatively, the hermetically sealed enclosure can comprise through vias for establishing an electrical contact from the inside of the enclosure with the outside, e.g. for contacting a contact pad at the outside of the enclosure.

So at least one of the substrate layers, for example the base cover layer, may comprise one or more through vias for electrically contacting the function zone with the surrounding outside of the enclosure, for example a contact pad on the lower side of the base cover layer.

The substrates of the enclosure may comprise a thickness of below 3 mm, for example below 1500 μm, below 500 μm, below 120 μm or below 80 μm. The base cover layer and/or the top cover layer may also be thinner than the one or more intermediate layers, for example comprising half the width of the intermediate layers or less. The enclosure may comprise a size of 10 mm×10 mm or less, for example 5 mm×5 mm or less, 2 mm×2 mm or 1 mm×1 mm or less. Also, the enclosure may comprise a height which is greater than its width.

According to the invention is also provided the use of a hermetically sealed enclosure for making a medical implant, a micro lens compound, a micro-optical chip, a pharma packaging, or an LED device.

Further according to the invention is also provided a method of providing a hermetically sealed enclosure, for example as explained in detail above and below, wherein the enclosure encloses a function zone such as a cavity, the method comprising the steps of providing a base substrate and aligning a cover substrate above the base substrate in such a way, that at least one contact surface is arranged between the base substrate and the cover substrate.

In other words, the substrate layers (e.g. base substrate and cover substrate) are stacked in direct contact with each other, which is, they are arranged next to each other. Care is taken for that no other and/or disturbing material is arranged in between the substrate layers, so that the substrate layers are in close and planar/laminar contact with each other. For example, the base substrate is provided in direct contact with the cover substrate, in particular avoiding that other material or a spacing or gap is residual between the bas substrate and the cover substrate. If, for example, more than two substrates are to be provided, the base substrate will be in close and direct contact with the intermediate substrate and the intermediate substrate, on its other side, in close and direct contact with the cover substrate. This said, the substrates are provided proximately neighboring the respective next substrate.

Thereafter, the substrates are being welded by the new laser welding method, wherein a substrate layer is welded directly with the neighboring substrate layer without the need for additional, and/or other and/or non-aerial material or intermediate layers. The substrates are being welded directly with each other, so that the laser weld line, which is put into the aerial contact area/zone between each two substrate layers, connects in a non-detachable manner these proximately neighboring substrate layers. The melting zone of the laser weld line therefore is situated at the same time in both substrates which are welded, and goes seamless from the first substrate (base substrate) to the second substrate (cover substrate).

Therefore, a proximate, aerial or even full-aerial transition is established, which is, as the case may be, a substrate-substrate-transition or a glass-glass-transition. A locally limited volume is established as welding zone (laser weld line), in which a transfer or blending of the materials of the neighboring substrate layers is present, which may be planar. For example, material from the first substrate (base substrate) enters into the second substrate (cover substrate), and vice versa, so that in the welding zone a complete material blending of the neighboring substrates is present. The laser weld line may therefore also be described as convection zone.

The new laser welding technique may be advantageously provided without the need for any intermediate layers or materials, such as glass frit, foils or adhesives, which were needed in formerly known techniques. The new non-detachable connection in between the substrate layers may advantageously be provided without limiting intermediate layers or additional materials, such as bonding materials. This facilitates manufacturing, renders such additional material unnecessary, increases the robustness and/or hardness of the enclosure and allows for a safe and hermetic sealing of the function zone (cavity). For example, the laser weld line can be identified in the end product by the specific local change of refraction index of the material in the small melting zone.

For example, if the substrates are not provided fully planar, which may be the case due to e.g. production tolerances, such a gap in between the substrates (base substrate and cover substrate) could be tolerated, for example, if the gap is smaller or equal to 5 μm, such as smaller or equal to 1 μm. Such a gap may originate from tolerances of substrate production, or by thermal influence, or even by inclusions of particles, such as dust. Even when such a tolerable spacing is present between the substrates, which is according to the present invention regarded as proximate neighboring each other, it is possible to weld such that the welding zone (laser weld line) comprises a width of about 10 to 50 μm, so that hermetic sealing is performed. Also in this case the melting zone goes from the first substrate seamless into the second substrate. So to say, the laser weld line is brought into the contact area between the first and second substrate and merges the substrates directly with each other to an inseparable compound. By the welding process, material of both substrates, which is situated in the laser weld line, is directly molten, and material from the first substrate blends with material from the second substrate to form an inseparable one-piece compound. The enclosure made thus comprises finally a monolithic compound, at least in the laser weld line.

The method of hermetically sealing an enclosure thus comprises hermetically sealing the function zone by introducing a first laser weld line in the enclosure; and introducing a second laser weld line at the same position as the first laser weld-line or at a position close to or overlapping with the first laser weld line; and relieving stress in the area of the first laser weld line of the enclosure by introducing said second laser weld line.

In the method a laser beam source can be used to introduce the laser weld lines into the enclosure. The laser beam can be guided around the function zone for making the laser weld line along the contact area between the base substrate 3 and its neighboring substrate, e.g. the cover substrate.

Said laser source can be a pulsed laser source, wherein several laser pulses are introduced along the laser weld line, so that a continuous or continuous-like weld-line is composed from the several laser pulses.

According to the invention there is also provided a tempered sealed enclosure made by the method as depicted above and below.

The invention is described in more detail and in view of exemplary embodiments hereinafter.

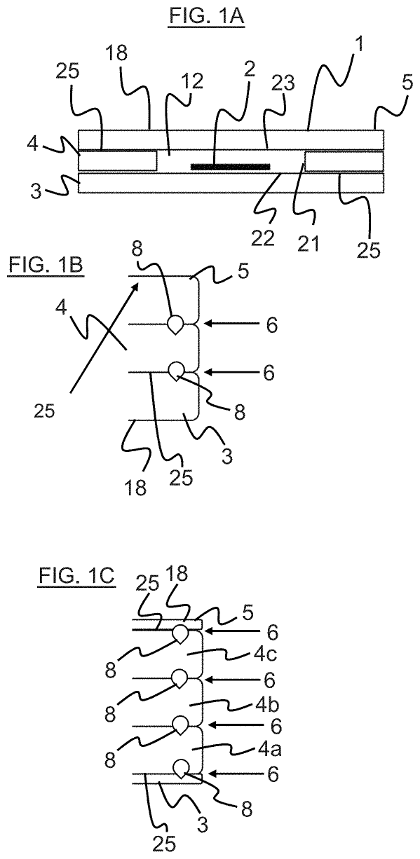

Reference is now made to the attached drawings wherein like numerals have been applied to like or similar components. FIG. 1A shows a sectional view of an embodiment of an enclosure. An intermediate layer 4 is arranged on top of the base layer 3, where the function zone 12 is arranged in an intermediate layer 4 of the enclosure 1. On top of the intermediate layer 4 a cover layer 5 is arranged. All of the layers 3,4,5 can also be multi-layered components, e.g. chemically hardened glass with a dielectric coating that covers one or both side partially or wholly. This can also be the case for all of the following descriptions. The function zone 12 is a cavity, where a function component 2 such as an electrical component or a lens is situated inside the cavity 12. Between the base layer 3 and the intermediate layer 4 on the one side and the intermediate layer 4 and the cover layer 5 on the other side there is situated a respective contact surface 25. The base layer provides the bottom 22 of the cavity 12, the intermediate layer 4 comprises the side wall 21, where the cover layer 5 comprises the top 23 of the cavity 12.

Referring to FIG. 1B, a detail of a corner of the enclosure 1 is shown, where the interface zone 8 welded by a laser beam is shown in more detail. In this embodiment, there is one interface zone 8 in each contact surface 25, where each interface zone 8 is a laser weld line going around the cavity 8. In other words, each interface zone 8 constitutes a circumferentially closed ring or closed line.

FIG. 1C shows another example for an enclosure, where several intermediate layers 4a, 4b, 4c are used, and a stack 18 of layers 3, 4a, 4b, 4c, 5 is formed. Again, at each contact surface 25 there is arranged a respective laser weld line 8. As a result of the laser welding, the respective layer or substrate is firmly bonded or affixed to the neighboring layer. The top layer 5 of this example might be a glass layer. The intermediate layers 4a, 4b and 4c may also be provided as a multilayer compound 4, and the cavity 12 can then be cleared e.g. by an abrasive method.

For example, the base substrate can be a wafer or a printed circuit board, for example made from aluminium nitride. The function zone 13 (or cavity 12) can also be formed as a recess e.g. in the base layer 3, made e.g. by an abrasive method such as sandblasting.

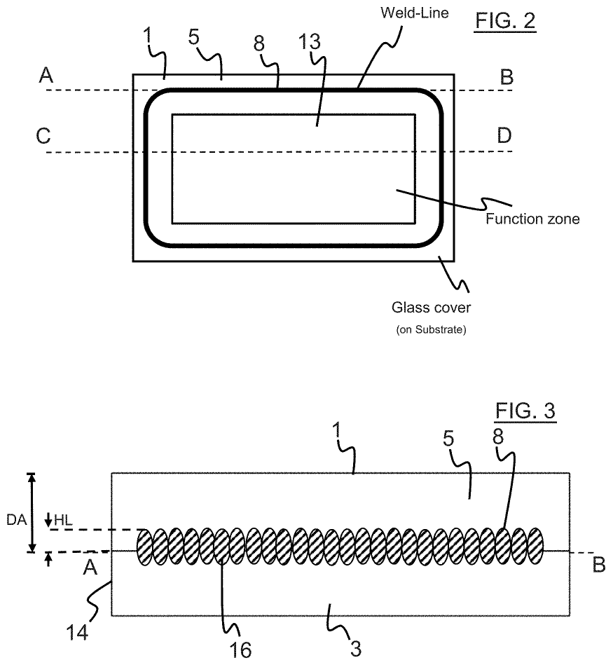

FIG. 2 shows a top view of an enclosure 1 provided according to the invention, where the circumferential laser weld line 8 encloses the function zone 13. The function zone 13 can be designed to meet different requirements according to the needs, for example this can be an optical receptor, or a technical, electromechanical and/or device 2 arranged in the function zone 13. It is also possible, that several different tasks are accomplished by the function zone 13, e.g. in that different devices 2 are installed in a function zone 13.

Referring to FIG. 3, another sectional view of an embodiment of the enclosure 1 comprising a base layer 3 and a cover layer 5, both in the form of substrates. In other words, the enclosure 1 comprises two layers, a base substrate 3 and a cover substrate 5. Further, FIG. 3 indicates how a laser weld line 8 is typically composed, which is, that a multitude of laser pulses 16 is set so close to each other and aligned in the form of a line so that the material of the base substrate 3 and the cover layer 5 melts and merges with each other, for example without any gap, so that as a result the function zone 13 or the cavity 12 is hermetically sealed by the laser weld line 8 or the laser weld lines 8 surrounding the function zone 13 or the cavity 12.

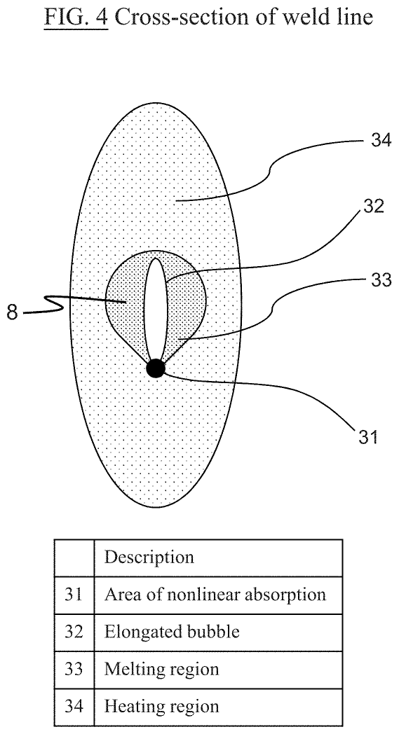

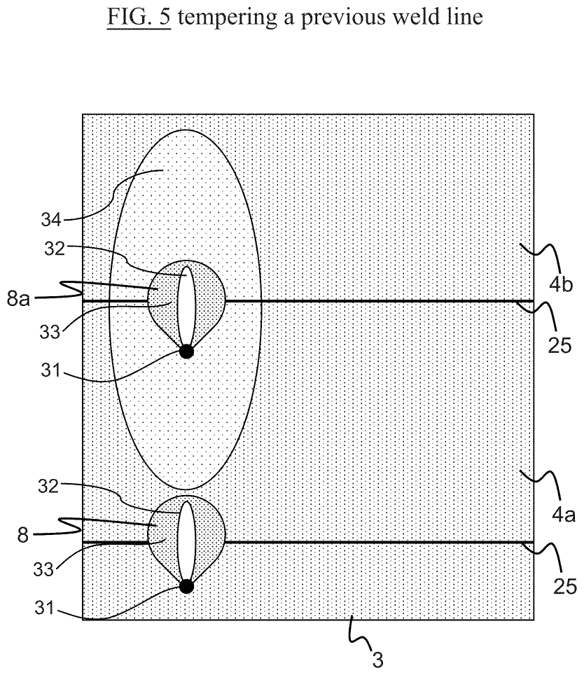

Referring now to FIGS. 4 and 5 it is explained how with the introduction of several close laser weld lines 8 the stress in the material of the various substrates 3, 4a, 4b, 5 etc. may be reduced in an inventive manner. FIG. 4 shows a cross-section of a typical weld line 8, which is, the cross-section of a modification caused by several laser pulse shots 16, where the many shots of laser pulses 16 cause through overlapping nonlinear absorption zones a line where heat accumulation takes place and a laser weld line 8 forms. The cross-section through such a weld line is depicted in FIG. 4. It comprises several distinguishable areas. First an area of nonlinear absorption 31, which corresponds more or less with the laser focus and which is in the size of a few micrometres. Above that zone 31—when the laser 9 is shot from above the substrate stack 18, an elongated “bubble-shaped” region 32 (also referred to as “bubble 32” due to its typically quite characteristic shape comparable to an elongated bubble) can be formed which is only a few micrometers in width, but typically up to several tens of micrometers in height. Around that bubble-shaped region 32 there is situated a melting region 33 with a width w and a height h, where temperatures above Tg may be reached and the glass therefore (after cooling or dissipation of warmth) has resolidified. The melting region 33 with the included elongated bubble 32 can usually clearly be identified, e.g., with a light microscope, since its density and with this the refractive index has changed with respect to the surrounding glass. In some cases, the area of nonlinear absorption 31 can also be observed as optical damage on the lower tip of the melting region 33.

Around the melting region 33 and in a heated region 34 the glass has received from heat accumulation of the multiple laser shot 9 an amount of energy by which its temperature raises to lower than Tg (the melting temperature of the respective material) but still significantly above room temperature. Due to heat diffusion this temperature is not the same in every corner of the heated region 34. The size of the heated region 34 scales with the size of the melting region 33. Thus, the dimensions and in particular the boundary of the melting region 33 can serve as an indicator for the dimensions of the heated region 34.

According to the present invention it has been found out that any weld line 8 may also double serve as a local heat source for tempering the substrate material. Tempering is typically known as a heat treatment of glass in order to make it stronger, more resistant to heat and breakage. This is the same for the tempering presented in this disclosure, but however without the several disadvantages of any tempering method as known in the art. Here, given a certain profile of the weld line 8, which is characterized by height h and width w of the melting region 33, the heat region 34 may be placed by a weld line 8 and with respect to the to be tempered region or feature. By such a tempering feature, former weld lines 8 may be stress reduced, or even micro-cracks may be removed from the material.

Typical values, which have been found out which serve as an improvement or tempering of the substrate layer material, are presented in Table 1 below:

TABLE 1
Typical values for tempering

| Feature | Benefit | X | Y |
|---|---|---|---|
| Other weld line | Stress reduction | 0.5 w-5 w | 1 h-5 h |
| Edge of cavity | Healing of micro cracks | 1 w-2 w | n.a. |
| Pre-scored plane | Weakening of cleaving | 1 w-2 w | n.a. |
| | tension; healing of | | |
| | micro cracks | | |
| Waveguide | Gradient refractive | 1 w-1.5 w | 1 h-1.5 h |
| | index reduces losses | | |
| Interface between | Stress reduction, | n.a. | 1 h-1.5 h |
| two layers | | | |
| Glass-Coating- | Hermetic sealing of | n.a. | <1 h |
| Glass interface | coated interface | | |
| (hardened) | Localized stress | >2 w | >2 h |
| surface/edge | profile adaption | | |
| Metal filled | Better metal | 1 w-1.5 w | 1 h-1.5 h |
| through glass vias | retainment in hole | | |
| Dicing line | Toughened edges of | 0.5 w-10 w | n.a. |
| | singulated chips | | |
| Outer Conducting | Avoidance of detrimental | 1 w-2 w | 1 h-2 h |
| layer | effects like delamination | | |
| | or thinning | | |

In Table 1 for different purposes (“feature”) the respective benefit which is obtained when tempering is done is indicated. In the third and fourth columns, typical values are listed which typical widths may be obtained for the respective zone improved by the “laser induced tempering” method presented herein. Coordinates indicated in Table 1 by “X” and “Y” may, for example, be indicated with respect to the feature which is to be tempered. W refers to the width of the melting region 33 of the laser weld line 8, where h refers to the height of the melting region 33. The melting region introduced by the laser weld line 8 may typically be in the size of about w=50 μm, maybe ±10 μm, and/or h=100 μm, maybe ±20 μm.

For example, for the case that one laser weld line 8 has been shot into a substrate layer, then the material of the respective substrate layer has received an amount of stress which is stored therein. By shooting a second laser weld line 8 close to the first one, the stress introduced by the first laser weld line 8 can be reduced, and may even be cancelled out as will be explained further below. In another example given in Table 1, when improving an edge of a cavity 12, micro cracks can be eliminated, so that the cavity 12 is more stable and comprises a higher resistance with respect to any forces from outside or inside.

In yet another example given in Table 1, in a pre-scored plane cleaving tensions can be healed and at the same time also micro cracks reduced or eliminated. In a waveguide element, for example, a gradient refractive index can be set up which may reduce losses of the waveguide.

In an interface between two layers, again stress and micro cracks can be reduced. For example, on a glass-coating-class interface, a hermetic sealing of the coated interface can be performed. When the surface or edge has been hardened in other ways, e.g. by chemical hardening or temperature hardening, or even for any surface or edge, a localized stress adaption profile can be performed in the material. In the case when metal is filled through glass vias a better metal retainment in the hole can be achieved, as given in Table 1. Close to any dicing line, the edges of the singulated chips can be toughened. Regarding an optional outer conducting layer, some detrimental effects like delamination or thinning may be avoided.

Referring to FIG. 5, the lower laser weld line 8 has been performed first, and a “curing” second laser weld line 8a has been performed thereafter. Any distortion which had been introduced by the first laser weld line 8 has been neutralized by performing the second laser weld line 8a. In this example, the two laser weld lines 8, 8a achieve the additional feature that substrates are welded together, where the first laser weld line 8 welds the base substrate 3 to the first intermediate layer 4a, and the second laser weld line 8a welds the first intermediate layer 4a with the second intermediate layer 4b along each contacting area 25.

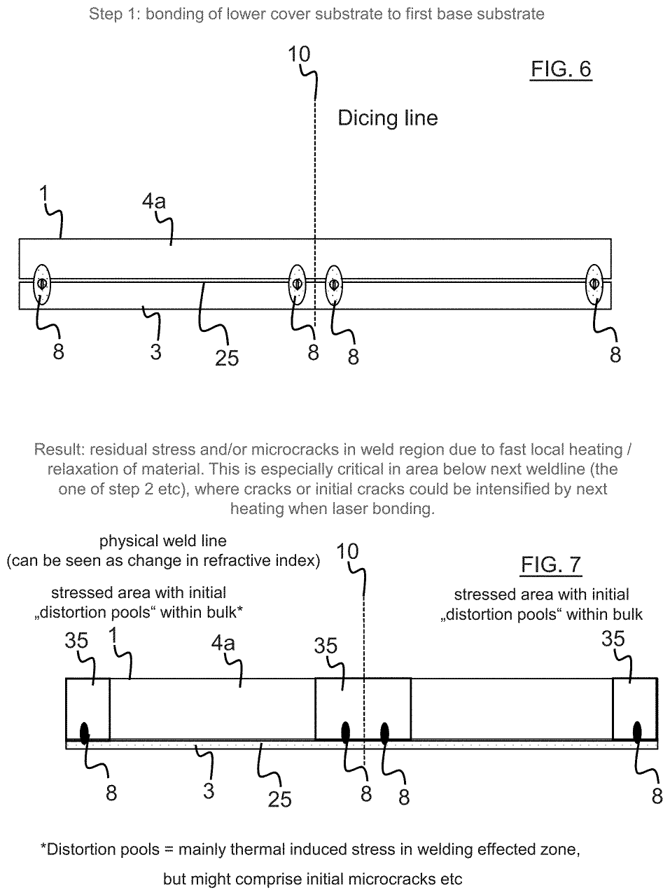

The FIGS. 6 to 14 show an exemplary way of composing an enclosure 1 provided according to the invention, which is also a method of manufacturing the same. The enclosure 1 of this embodiment is covered on both sides by a cover substrate which may be thinner than the “inner” substrates, but this is of exemplary reason only. Introducing additional cover substrates on both sides of the template may be advantageous as will be described below in more detail, as has been found out according to the present invention, that by introducing additional cover substrates it can be possible to eliminate even more stress in the materials of the inner substrates.

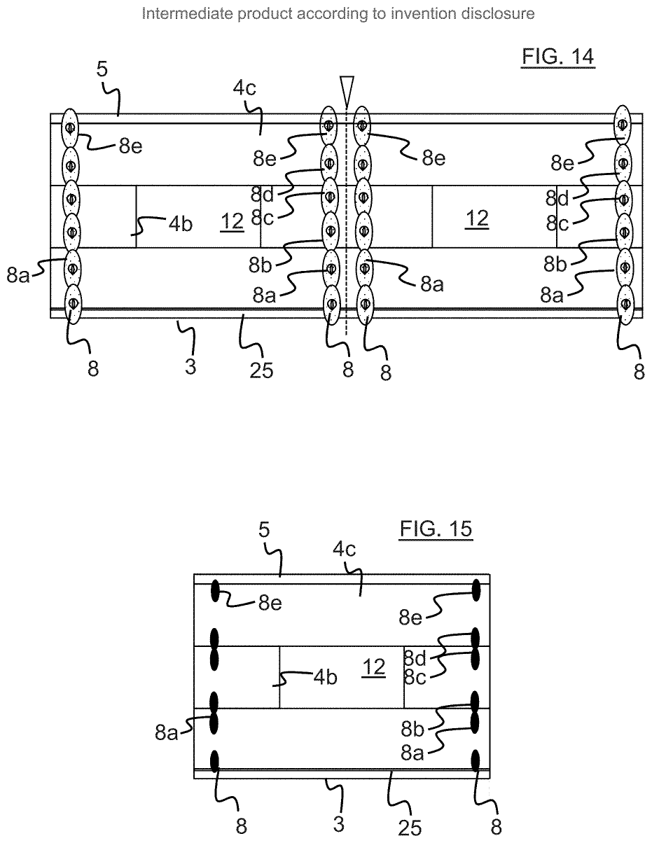

It should be noted that it is not necessary to perform the steps as shown in FIGS. 6 to 14 in an isolated manner, but rather that it is possible to provide a full stack 18 as e.g. shown in FIG. 14 and to laser weld each laser weld line 8 in a full stack 18 rather than in a layer-wise manner providing each layer after the next higher layer has been provided.

Additionally, it might be noted, that in FIGS. 6 to 14 a number of enclosures 1—here two enclosures 1—are prepared and made at the same time with the same process of manufacturing the same, and afterwards the two enclosures 1 are separated from each other along the dicing line 10 indicated e.g. in FIG. 6. However, of course each enclosure 1 can also be prepared and made separately.

According to FIG. 6, a lower cover substrate 3 is provided and a first intermediate layer 4a is arranged on top of the lower cover substrate 3. Thus, it could be said that an intermediate product 1 is formed, but in a simple embodiment an enclosure 1 could yet be formed by adjoining two layers and welding each enclosure 1 by at least one laser weld line 8.

FIG. 7 indicates stressed areas 35 in the first intermediate layer 4a, introduced by forming the laser weld line 8 in the material of the enclosure 1. In this example, forming the laser weld line 8 in the material results in residual stress and/or micro cracks in the weld region 35, which occurs due to fast local heating and relaxation of the material and/or due to thermal differences in the material. For reasons of explanation it may be added, that such structurally weak areas 35 can even be worsened when in an area below the next/second weld line cracks or initial cracks could even be intensified.

The “physical” weld line 8, which corresponds to the melting region 33, can be seen by a change in the refractive index at its outer circumference. “Above” this physical weld line 8—when the laser is shot into the material also from above—there occurs the stressed area 35 with an initial “distortion pool”. The distortion pool results from mainly thermal induced stress in the welding effected zone 35, but might comprise initial micro cracks or the like.

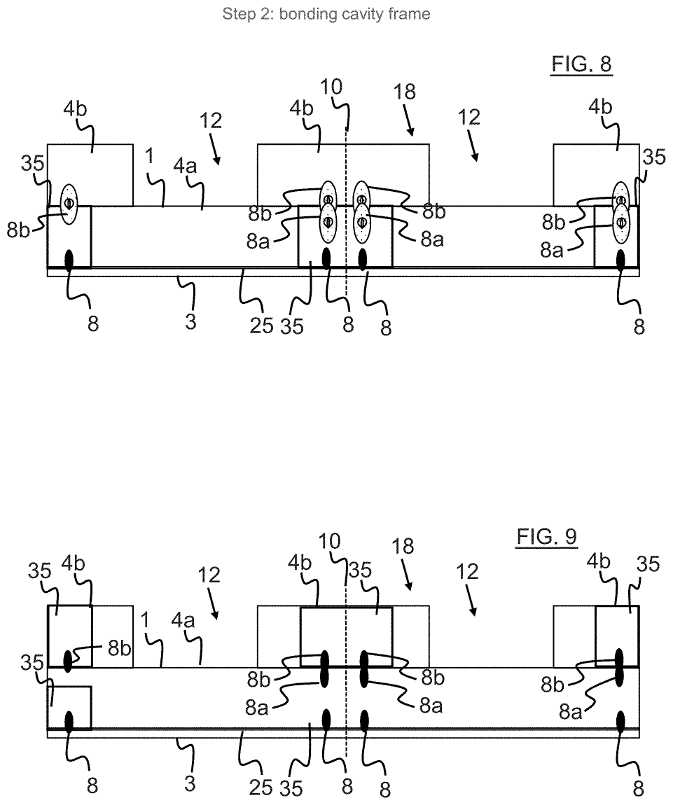

FIG. 8 shows the substrate stack 18 in the moment of placing a second and a third weld line 8a, 8b into the enclosure 1, where a second intermediate layer 4b is arranged on top of the first intermediate layer 4a. The second intermediate layer 4b constitutes the rim 21 or the “frame” of the future cavities 12. The stressed zones 35 are indicated similar to the embodiment of FIG. 7 as in the moment where the embodiment of FIG. 8 is shown the stressed zones 35 still persist, but will decrease thereafter as indicated in FIG. 9. The first weld line 8 has already cooled down, whereas in the second and third “hot” weld lines 8a, 8b still the heating region 34, the elongated bubble 32, the melting region 33 and the area of nonlinear absorption 31 are indicated (see e.g. FIG. 4 for details). The contact surface 25 between the first intermediate layer 4a and the second intermediate layer 4b is welded for the most part by the two weld lines 8a and 8b, whereas at the left part of FIG. 8 it is indicated, how the material alters when only one weld line 8a is used.

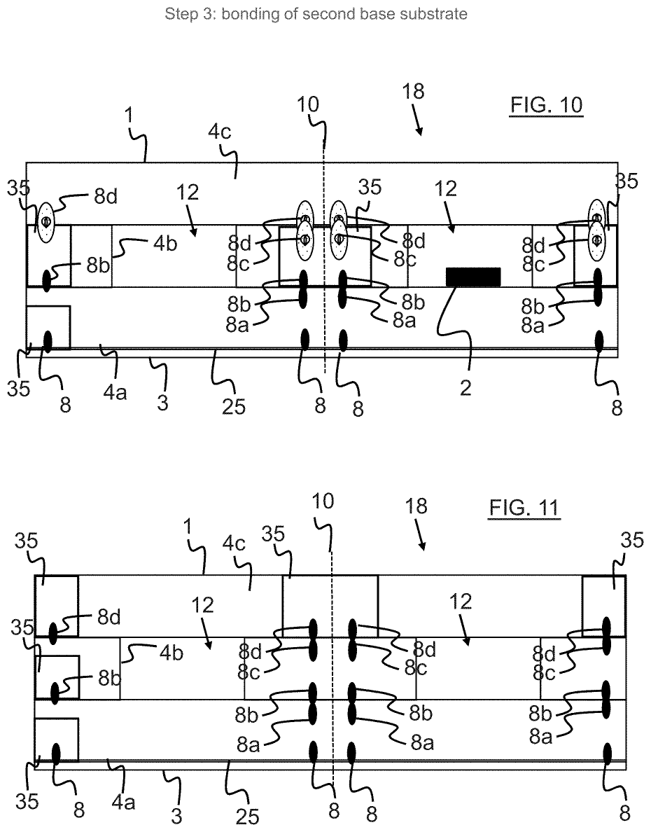

Referring to FIG. 9, the enclosure 1 after the welding step shown in FIG. 8 has cooled down and the stressed areas 35 have evolved. As can be seen in FIG. 8 in the middle and right-most part, where the two weld lines 8a and 8b have been set, the material of the first intermediate layer 4a is stress-free. It has been found out that if the two weld lines 8a, 8b are set close to each other, e.g. one below and one above a contact surface 25 which is to be welded, that then the stress and even the maybe present micro cracks can be “cured” in the material around the welding zones. This is of particular interest, as the contact surfaces 25 in between any substrate layer of the stack 18/the enclosure 1 typically constitutes one of the most critical areas with respect to its integral stability. Now new stressed zones 35 have evolved in the second intermediate layer 4b surrounding the later-to-be cavities 12; these stressed zones 35 can be relieved of stress in a subsequent step (see FIG. 10).

Reverting now to the left part of FIG. 9 only one second weld line 8a has been introduced here in the material. In this area, stress persists in the material of the first intermediate layer 4a thus resulting in a weaker material composition, which is, worse withstanding any bending forces or impacts, where even micro cracks may persist.

FIG. 10 shows a next consecutive step of manufacturing an enclosure 1 provided according to the invention. A third intermediate layer 4c is positioned on top of the second intermediate layer 4b so as to close the cavities 12. If any electronics or function component 2 should be inserted into the cavity 12 or the function zone 13, then in this exemplary method of manufacturing an enclosure 1 it should be added prior to the step shown in FIG. 10. By exemplary reasons, the left cavity 12 comprises a function component 2. A third and fourth laser weld line 8c and 8d has been shot at the enclosure 1 leaving a relatively hot zone, which has yet to cool down. The stress zones 35 indicated in this example correspond to those shown in FIG. 9, as the laser weld zones are still hot and the stress relief in the respective zones did not yet has come to pass. The contact surface 25 between the second and third intermediate layers 4b, 4c has been welded with the two laser weld lines 8c and 8d.

As can be retrieved from FIG. 11, the stress zones 35 in the middlemost and right part of the figure have disappeared, meaning that the stress has been reduced or eliminated in the material of the enclosure 1. But in the left part of FIG. 11, which is shown for comparative reasons only, where each contact surface 25 has only been welded with each one laser weld line 8b, 8d stress persists in the material, as is indicated with the stress zones 35 which also remain in the first and second intermediate layer 4a, 4b.

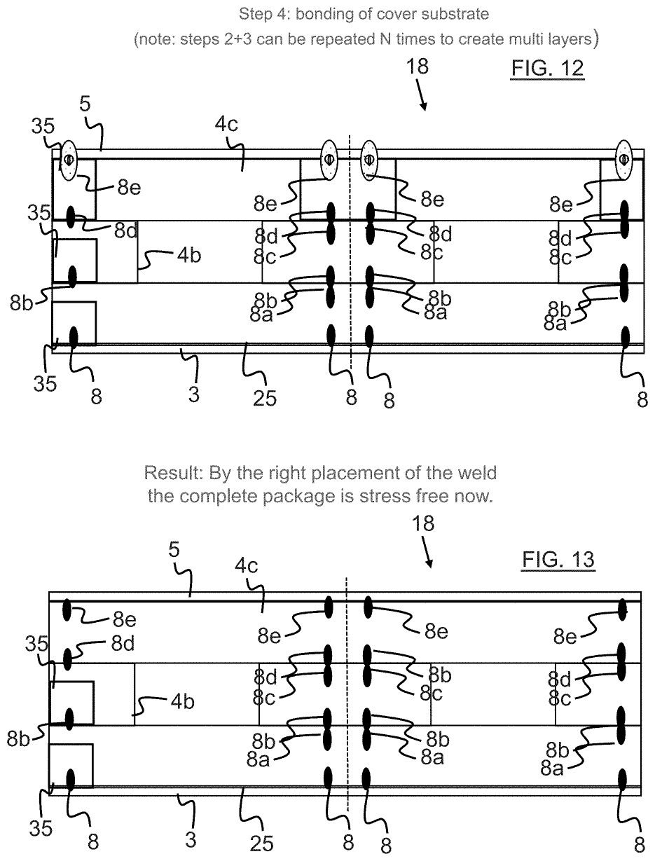

Referring now to FIG. 12 a consecutive step for making an enclosure 1 provided according to the invention is shown, where an upper cover layer 5 is arranged above the third intermediate layer 4c and welded to the same with one additional weld line 8e. Again, the very moment when the laser is shot into the material of the enclosures 1 is indicated with FIG. 12, so that the stress zones 35 are the same with respect to the situation shown in FIG. 11. A full stack 18 of substrates is finished. In FIG. 13, the resulting stress relief can be seen, as in the middle part and the right part no stress zones 35 remain. In the left part, which again is indicated only for comparative reasons, in order to easier understand the reasons, and where only one laser weld line 8 is used for welding each contact surface 25, still stress zones 35 persist in the material, thus weakening the same. But in the third intermediate layer 4c, where two laser weld lines 8 d and 8e are situated, a full stress relief can be achieved. As is now clear from FIG. 13 and the before-mentioned explanations, the bottom and top cover layers 3 and 5 allow in the end for an enclosure, which gains benefit from all advantages of being laser welded, but which does not suffer from additional stress in the material. The material is tempered, so that micro cracks are equalled, but without the disadvantages of classical tempering methods. For example, electronics or function components 2 can be installed in the enclosure 1, which would not be possible with normal tempering due to the necessary high temperatures throughout the whole material of the enclosure 1. But however, the outermost layers, which are the lower cover layer 3 and the upper cover layer 5, can for example be tempered (which is: relieved of stress) by classical methods, which is, by heating up the layers 3, 5 above a melting temperature.

Referring now to FIG. 14, an embodiment is shown where a full stack 18 of substrates 3, 4a, 4b, 4c and 5 is arranged on each other, where the laser weld lines 8, 8a, 8b, 8c, 8d and 8e are introduced into the material one after another. Finally, the two enclosures 1 are cut or separated along the dicing line 10, and with FIG. 15 a single enclosure 1 is shown which can be obtained with the above explained method of manufacturing the same.

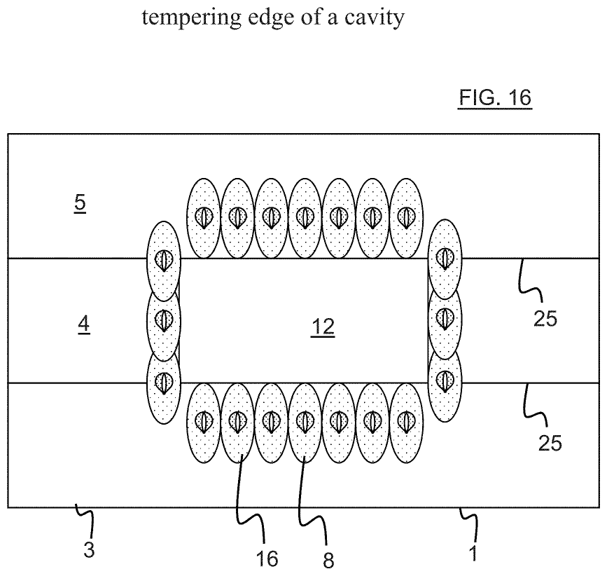

With FIG. 16 another example of tempering around the edge of a cavity 12 is shown. An at least two-dimensional weld line 8 is performed around the cavity 12, where by the laser weld line 8 not only the formerly separated substrates 3, 4 and 5 are welded together, but also any stress in the zone surrounding the cavity 12 is eliminated or at least significantly reduced, including elimination of possible micro cracks. Such micro cracks can be persistent in the material, or be brought in the material e.g. when cutting out material for making the cavity 12. A subsequent line of laser shots 16 is set close to each other to build the laser weld line 8 around the cavity 12.

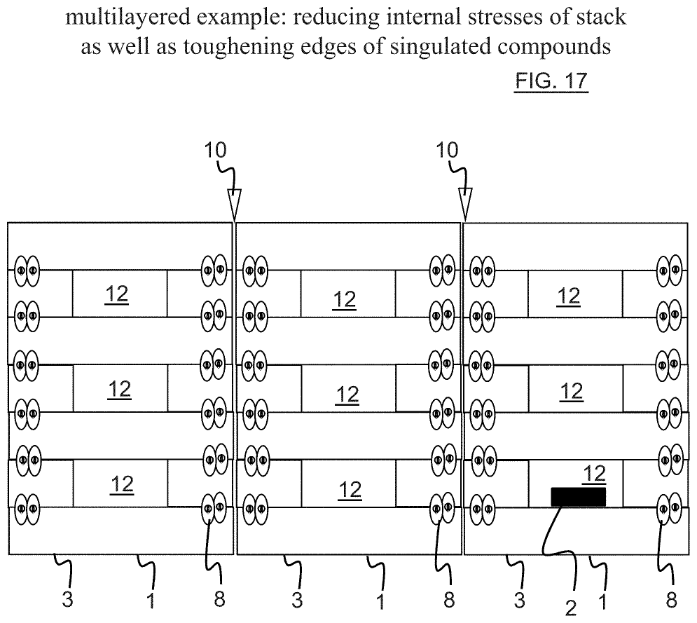

Referring to FIG. 17 a multi-layered example is shown, where each enclosure 1 comprises three cavities 12, and at the same time where three enclosures 1 are made together in the same manufacturing process, but are separated in a separation step after finishing laser welding for example along the dicing lines 10 indicated in FIG. 17. Several laser weld lines 8 are introduced into the material as described above in order to eliminate or decrease stress in the material of the enclosures 1. Each cavity 12 typically comprises a function component 2, whereas such a function component 2 is indicated in one cavity 12 only for reasons of ease of understanding.

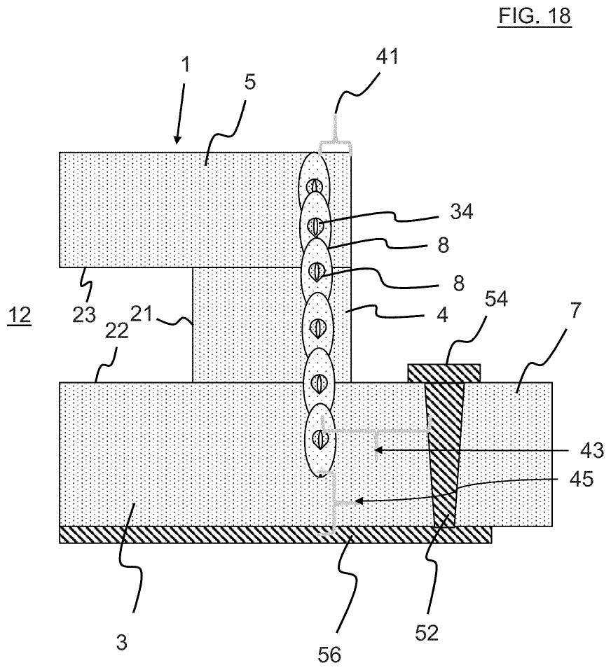

FIG. 18 shows a side-view orientation of a detail of an enclosure 1 having a cavity 12, where the upper substrate 5 and the lower substrate 3 as well as the cavity 12 are only partly shown. The laser weld line 8 encircling or surrounding the cavity 12 is indicated with a safety margin 41 with respect to the edge of the layers 3 and 4. The safety margin 41 helps to assure, that the laser weld line 8 is properly made in the material of the enclosure 1. The safety margin or prescored plane 41 may comprise a width of 0.5 w to 2 w.

As shown in FIG. 18, the lower substrate 3 comprises greater dimensions than the neighboring substrates 4, 5, where the lower substrate 3 extends farther out by an extension part 7. The extension part 7 comprises the width 47, where generally a rather small width 47 is desirable in order to reduce overall size of the enclosure 1. Due to similarity in construction details, FIGS. 18 through 21 may show the same embodiment, such as a hermetical biomedical implant with electrical contacts.

An extension portion 7 may be used to arrange a contact pad 54 sideways to the cavity 12 and thus, accessible from above. A through glass via 52, which for example is metal filled, may connect the contact pad 54 with a conducting portion 56, such as a conducting stripe installed below the base substrate 3. The through glass via 52 is arranged spaced from the laser weld line 8 by a margin 43, in order that the through glass via 52 is not changed or disturbed when the laser weld line 8 is generated in the enclosure 1. The safety margin 43 between the weld line 8, 8a, 8b, 8c, 8d, 8e and the through glass via 52 may, for example, be in the range of 1 w to 1.5 w horizontally, as depicted. If the weld line 8, 8a, 8b, 8c, 8d, 8e is situated or arranged beneath the through glass via 52, the corresponding safety margin may be in the range of 1 h to 1.5 h.

The conducting portion 56 may comprise another electrical contact zone in order to establish electrical contact with the contact pad 54. The safety margin 45 between the conducting portion 56 and the weld line 8, 8a, 8b, 8c, 8d, 8e could be chosen to about 1 h to 2 h in a vertical arrangement as depicted, and/or, in the case of a horizontal arrangement, about 1 w to 2 w.

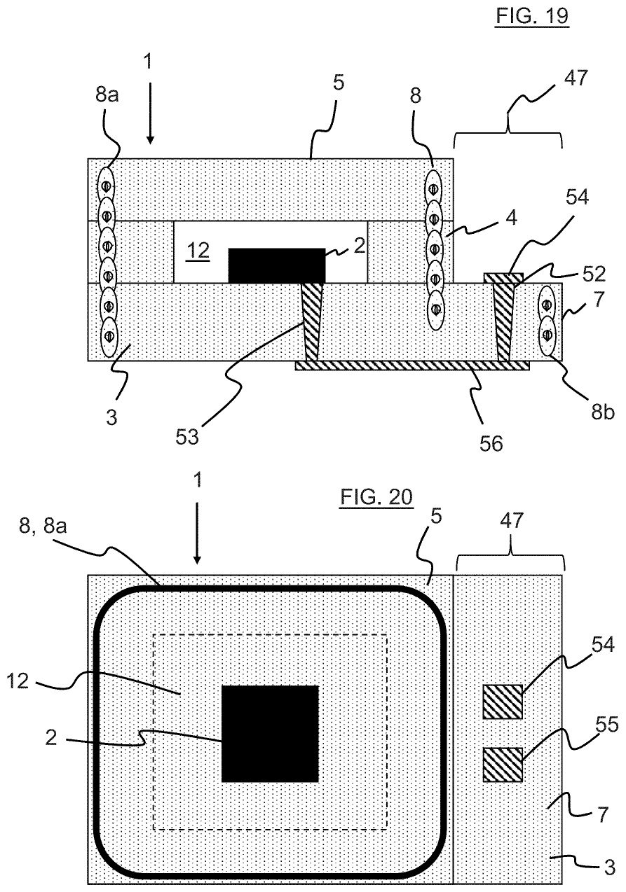

Referring to FIG. 19, a side-cut view of an enclosure 1 having a cavity 12 shows the laser weld line 8, 8a surrounding the cavity 12. Same reference signs as used with respect to FIG. 18 indicate same features. The enclosure 1 may be used as hermetical biomedical implant with electrical contacts 54, 55 (see FIG. 20). The contact pad 54 situated on the extension part 7 of the lower substrate 3 is connected by through glass via 52 with conducting portion 56 and further by through glass via 53 with function component 2 arranged in the cavity 12. In other words, an electrical path 52, 53, 54, 56 is defined from the inside of the enclosure 1 to its outside, where a contact pad 54 may be contacted easily e.g. from above or from the side.

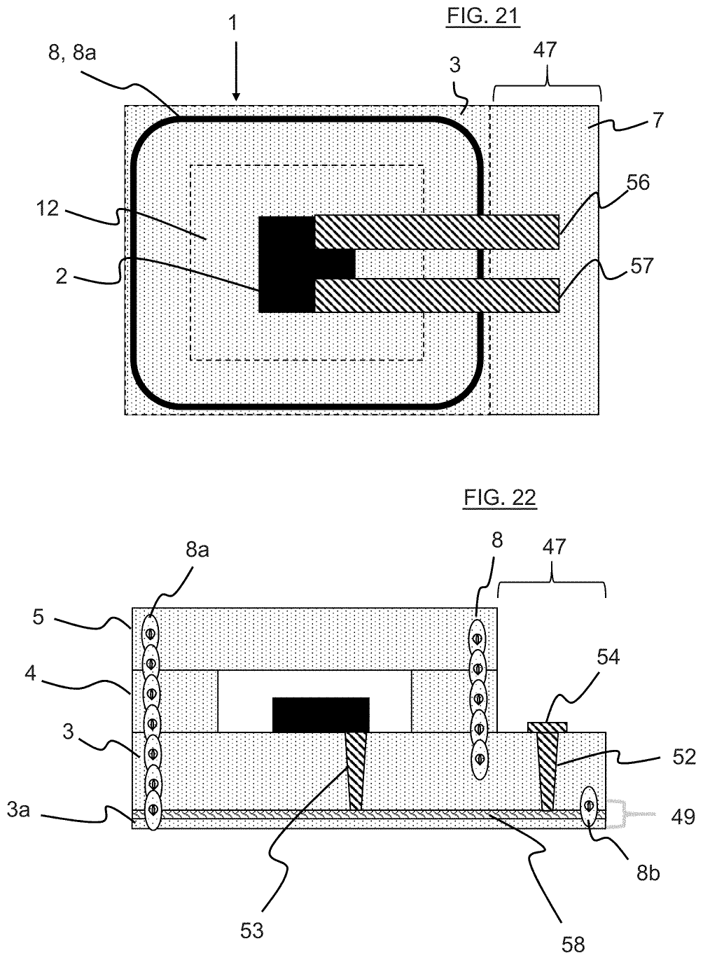

FIG. 20 shows a top view of an enclosure 1, for example the hermetical biomedical implant 1 with electrical contacts 54, 55 as also shown in FIG. 19, where the two contact pads 54, 55 may be identified on the extension portion 7 of the lower substrate 3. The laser weld line 8, 8a is drawn hermetically around the function zone 12, 13 with the function component 2. The two contact pads 54, 55 allow for ease of operation and electrical contacting. Next, FIG. 21 shows an enclosure 1 with electrical contact stripes 56, 57 in a bottom view, where the electrical stripes 56, 57 are separated from each other, and arranged below the lower substrate 3, in order to contact two electrical contacts isolated from each other. As is outlined with respect to the FIG. 18 or 19, for example, through glass vias 52, 52a, 53, 53a may be electrically connected with the contact stripes 56, 57.

Referring to FIG. 22, an enclosure 1 is shown comprising an encapsulated conduction layer 58 arranged below the base substrate 3 and encapsulated, in particular electrically encapsulated, by a thin substrate 3a, such as a cover glass 3a. The through-glass-vias 52 and 53 are interconnected each with the conduction layer 58, where the through-glass-via 52 contacts the connection pad 54 and the through-glass-via 53 contacts the function component 2 inside the cavity 12 of the enclosure 1.

On the side of the enclosure 1 where no electrical contacts need to be guided to the outside of the enclosure, the laser weld line 8a can be placed through the conducting layer 58. On the side comprising the extension portion 7, the laser weld line 8 ends next to the conducting layer 58 in order not to extend into or through said conducting layer 58. For example, another laser weld line 8b can be placed in the extension portion 7 and there providing hermetically seal of the enclosure and, alternatively or cumulative, securely mechanically connect at least one of the conducting layer 58 and the substrate 3a to the rest of the enclosure 1. Depending on the width of the conducting layer 58 as well as the positioning of the electrical contacts to be connected to the conducting layer 58 the laser weld line may be arranged also such that other portions than close to the edge of the enclosure 1 can be welded with the lower substrate 3.

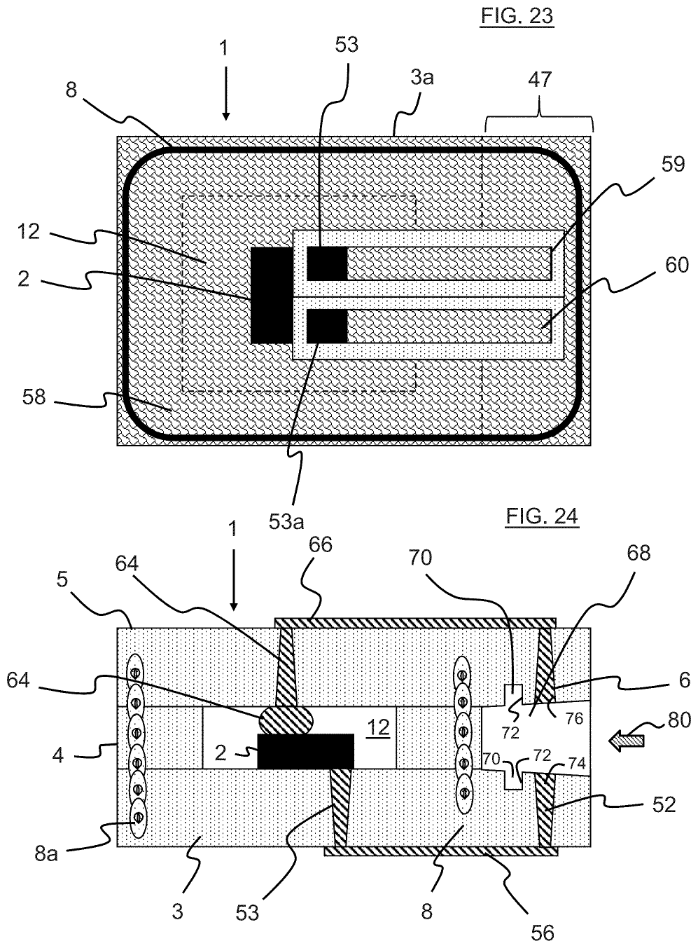

FIG. 23 shows a bottom view of an enclosure 1, where singulated conducting stripes 59, 60 are shown which have been separated from the conduction layer 58. Separate electrical contacts can thus be established in the conduction layer 58 easily, for example even by guiding distinguishing electrical contacts to different sides of the enclosure 1, including more than one side of the enclosure 1 (see e.g. FIG. 26). The conduction layer 58 may have the same extension dimensions as, for example, the lower substrate 3, but it may also be kept slightly smaller so that the encapsulation layer 3a may also isolate the conduction layer 58 at its sides.

FIG. 24 shows a sectional view of an enclosure 1 where top and bottom contacts 74, 76 are established in that electrical contacts are established on the lower side as well as on the upper side of the enclosure 1. For example, the upper contact 76 can be contacted to the function element 2 by an upper contact portion which contacts, on one side, by through-glass-via 62 with the upper contact 76, and on the other side by through-glass-via 64 and contact 65, such as a solder drop, with the function component 2. On its side, a bay 68 for housing a connector, such as a plug-type connector is established. Two separate electrical contacts 74, 76 are provided on the upper and lower side of the bay 68. One or more connector hold notches 70 may be provided to hold the connector in the bay 68, where upon releasing force on the connector a ridge or any means functionally coupling with the connector hold notches 70 may press against the connector holder 72 and keep the connector in the bay 68. Arrow 80 shows a possible insertion direction for said connector.

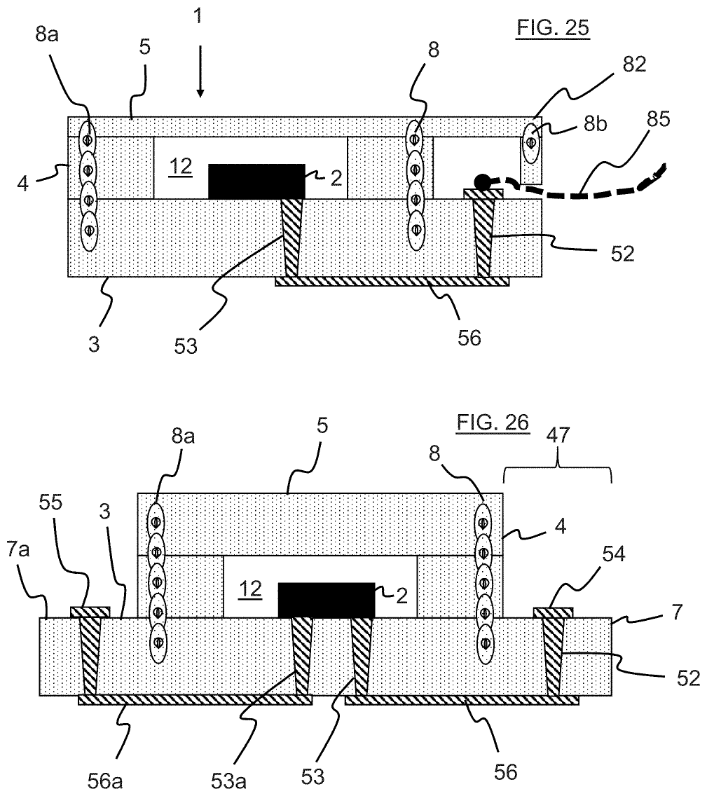

FIG. 25 shows another enclosure 1, where parts in other figures with same reference numerals show same or similar parts in this figure. A clamp portion 82 is established on one side of the enclosure 1, e.g. above the contact pad 54, here any electrical conductor can be clamped on the contact pad 54 by the clamp portion 82. For example, a nerve 85 can be contacted to the contact pad 54 and stimulated by electrical pulses from the function component 2 in the enclosure 1. All electrical parts of the enclosure 1, or at least those parts which need to be protected, may be encapsulated in the enclosure 1, where interaction with the outside can be established in different embodiments. The clamp portion 82 can constructionally be strengthened e.g. by another weld line 8b.

FIG. 26 shows another enclosure 1, where electrical contacts 54, 55 are provided on either side of the enclosure 1. Distinguishable contact portions 56, 56a are provided below the lower substrate 3, where different sides of the enclosure 1 could, for example, be marked with different coding, such as color, in order to facilitate electrical contact of the function component 2 with external contacts via the contact pads 54, 55.

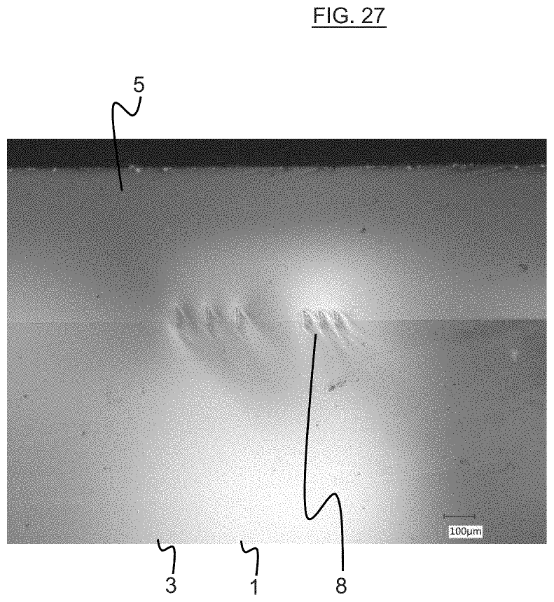

FIG. 27 shows a photograph of two substrates 3 and 5 laser welded together along a laser weld line 8, where the change in refractive property can be seen as well as the reduction of stress in the material, which shall serve as proof-of-principle of the above-indicated method and enclosure 1.

It will be appreciated that the features defined herein in accordance with any aspect of the present invention or in relation to any specific embodiment of the invention may be utilized, either alone or in combination with any other feature or aspect of the invention or embodiment. In particular, the present invention is intended to cover an enclosure 1 and/or a method of manufacturing an enclosure 1 configured to include any feature described herein. It will be generally appreciated that any feature disclosed herein may be an essential feature of the invention alone, even if disclosed in combination with other features, irrespective of whether disclosed in the description, the claims and/or the drawings.

It will be further appreciated that the above-described embodiments of the invention have been set forth solely by way of example and illustration of the principles thereof and that further modifications and alterations may be made therein without thereby departing from the scope of the invention. Finally, it is clear that features described, for example, in connection with a specific embodiment, such as with the enclosure, may also be combined with any other embodiment, such as with the substrate stack.

While this invention has been described with respect to at least one embodiment, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

### LIST OF REFERENCE SIGNS

1 enclosure
2 device or function component
3 lower substrate, base layer or lower cover substrate
3a substrate
4, 4a, 4b intermediate layer or multilayer compound
4c intermediate layer
5 upper cover layer, cover substrate
7, 7a extension portion
8, 8a, 8b, 8c, 8d, 8e, laser weld line
9 focussed laser beam
10 dicing line
12 cavity
13 function zone
14 edge
15 laser unit
16 laser pulse
18 stack of substrates; wafer stack
21 edge/rim of cavity
22 bottom of cavity
23 top of cavity
25 contact surface
31 area of nonlinear absorption
32 elongated bubble
33 melting region
34 heating region
35 stressed area
41 safety margin or prescored plane,
43 safety margin to through glass via,
45 safety margin to electrical conduction layer,
47 width of extension portion 7
52, 52a through glass via
53, 53a second through glas via
54 contact device or contact pad
55 second contact portion or contact pad
56, 56a contact portion or contact layer
57 second contact portion or contact layer
58 conduction layer
59, 60 conducting stripe
62 upper outer through glass via
64 upper inner through glass via
65 contact such as solder drop
66 upper contact portion or contact layer
68 socket (female connector)
70 connector hold notch
72 connector holder
74 first electrical contact, bottom contact
76 second electrical contact, top contact
80 plug-in direction for connector
82 flexible clamp
85 nerve

What is claimed is:

1. A substrate stack, comprising:
at least two substrates, the at least two substrates comprising a base substrate and a cover substrate;
at least one first laser weld line for welding the base substrate and the cover substrate; and
at least one second beam spot or at least one second laser weld line at least one of situated next to the at least one first laser weld line or positioned such that a stress reduction in the at least one first laser weld line is achieved by the at least one second beam spot or second laser weld line, thus improving the mechanical stability of the substrate stack.

2. An enclosure, comprising:
a substrate stack, comprising:
at least two substrates, the at least two substrates comprising a base substrate and a cover substrate, the base substrate and the cover substrate constituting at least a part of the enclosure;
at least one first laser weld line for welding the base substrate and the cover substrate, the at least one first laser weld line comprising a height (HL) in a direction perpendicular to its connecting plane; and
at least one second beam spot or at least one second laser weld line at least one of situated next to the at least one first laser weld line or positioned such that a stress reduction in the at least one first laser weld line is achieved by the at least one second beam spot or second laser weld line, thus improving the mechanical stability of the substrate stack; and
a function zone situated such that it is at least partly enclosed in the enclosure.

3. The enclosure of claim 2, wherein mechanical stress in the at least one first laser weld line is reduced by at least one of a stress reduction process step or by a crack reduction step.

4. The enclosure of claim 2, wherein the at least one first laser weld line introduces a stress zone in the enclosure, wherein the at least one second laser weld line is positioned in or next to the stress zone induced by the first laser weld line, and wherein the at least one second laser weld line relieves the stress zone so that at least one of a stress-free or nearly stress-free zone is established or the enclosure is stress-free or nearly stress-free.

5. The enclosure of claim 2, further comprising a cavity inside the enclosure or wherein the function zone is said cavity, the enclosure further comprising an at least two-dimensional laser weld line around the cavity for tempering edges of the cavity.

6. The enclosure of claim 2, wherein the at least one first laser weld line circumferes the function zone in a distance (DF), wherein the distance DF corresponds to double the height HL or less.

7. The enclosure of claim 2, wherein at least one of the following is satisfied:
the enclosure provides hermetical sealing for the function zone so that the enclosure is a hermetically sealed enclosure; or
the function zone is circumferentially enclosed in the enclosure.

8. The enclosure of claim 2, further comprising an elastic or flexible layer so that the enclosure is deformable.

9. The enclosure of claim 2, further comprising an inner coating zone.

10. The enclosure of claim 2, wherein the at least two substrates comprise at least one substrate provided as a multilayer compound.

11. The enclosure of claim 2, further comprising at least one intermediate layer positioned in between the base substrate and the cover substrate.

12. The enclosure of claim 11, wherein the function zone is situated in the at least one intermediate layer and is covered by the base substrate on its bottom side and by the cover substrate on its top side.

13. The enclosure of claim 11, wherein at least one of the following is satisfied:
the substrates comprise a thickness of below 3 mm; or
at least one of the base substrate or the cover substrate is thinner than the at least one intermediate layer.

14. The enclosure of claim 2, wherein the function zone is a cavity and wherein a function component is arranged in the cavity to be protected by the enclosure.

15. The enclosure of claim 14, wherein the function component comprises at least one of a power semiconductor, a GaN-LED, a SiC-power transitor, a GaAs-power transistor, or a GaN-power transistor positioned inside the cavity.

16. The enclosure of claim 2, wherein each laser weld line is situated such that it extends into two different substrates of the enclosure.

17. The enclosure of claim 2, wherein at least one of the substrates comprises through vias for electrically contacting the function zone with a surrounding outside of the enclosure.

18. The enclosure of claim 2, wherein at least one of the following is satisfied:
the enclosure comprises a size of 10 mm×10 mm or less; or
the enclosure comprises a height which is greater than its width.

19. A method of providing an enclosure, wherein the enclosure encloses a function zone, the method comprising:
providing a base substrate and aligning a cover substrate above the base substrate in such a way that at least one contact surface is arranged between the base substrate and the cover substrate;
hermetically sealing the function zone by introducing a first laser weld line in the enclosure;
introducing a second laser weld line at the same position as the first laser weld line or at a position close to or overlapping with the first laser weld line; and
relieving stress in an area of the first laser weld line of the enclosure by introducing the second laser weld line.

20. The method of claim 19, wherein a laser beam source is used to introduce the first laser weld line and the second laser weld line into the enclosure; and wherein a laser beam is guided around the function zone for making the laser weld lines along the contact area between the base substrate and the cover substrate.

21. The method of claim 20, wherein the laser beam source is a pulsed laser source and wherein several laser pulses are introduced along the laser weld lines so that a continuous or continuous-like weld-line is composed from the several laser pulses.
